(19) United States
(12) Patent Application Publication
(10) Pub. No.: US 2010/0156512 A1
(43) Pub. Date: Jun. 24, 2010

(54) CHARGE PUMP CONTROLLER AND METHOD THEREFOR

(75) Inventor: Hassan Chaoui, Toulouse (FR)

Correspondence Address: SEMICONDUCTOR COMPONENTS INDUSTRIES, LLC;INTELLECTUAL PROPERTY DEPT. - A700, 5005 E. MCDOWELL ROAD, P.O.BOX 62890, PHOENIX, AZ, 85082, US

(73) Assignee: SEMICONDUCTOR COMPONENTS INDUSTRIES, L.L.C., Phoenix, AZ (US)

(21) Appl. No.: 12/090,825

(22) PCT Filed: Jun. 13, 2007
(86) PCT No.: PCT/US2007/071122

§ 371 Date: Mar. 8, 2010

(51) Int. Cl. H03L 7/06

(52) U.S. Cl. 327/536

(57) ABSTRACT

In one embodiment, a charge pump controller is configured to a charge pump controller to charge a plurality of pump capacitors during a charging time interval and to sequentially form a plurality of discharge time intervals with a different pump capacitor coupled to supply a current to a load for each discharge time interval.

### BACKGROUND OF THE INVENTION

The present invention relates, in general, to electronics, and more particularly, to methods of forming semiconductor devices and structures.

In the past, the semiconductor industry utilized various methods and structures to form charge pump controllers there were used to provide an output voltage from an input voltage source, such as a battery. Typically, the charge pump controller was used to charge multiple capacitors from the input voltage and to couple the capacitors to provide current to a load. The prior charge pump controllers generally formed two time intervals where one time interval was used to charge the capacitors and a second time interval was used to discharge the capacitors. One such charge pump controller was disclosed in U.S. Pat. No. 6,198,645 that issued to Kotowski et al on Mar. 6, 2001. Because of the manner in which the capacitors were charged and discharged, there typically was a high in-rush current when the capacitors were charged and a ripple on the output voltage that resulted from discharging the capacitors.

Accordingly, it is desirable to have a charge pump controller that reduces the in-rush current and that reduces ripple in the output voltage.

### BRIEF DESCRIPTION OF THE DRAWINGS

FIG. 1 schematically illustrates an embodiment of a portion of a charge pump power supply system that includes an exemplary embodiment of a charge pump controller in accordance with the present invention;

FIG. 2 is a graph having plots that illustrate some of the signals of the charge pump controller of FIG. 1 in accordance with the present invention; and

FIG. 3 schematically illustrates an enlarged plan view of a semiconductor device that includes the charge pump controller of FIG. 1 in accordance with the present invention.

For simplicity and clarity of the illustration, elements in the figures are not necessarily to scale, and the same reference numbers in different figures denote the same elements. Additionally, descriptions and details of well-known steps and elements are omitted for simplicity of the description. As used herein current carrying electrode means an element of a device that carries current through the device such as a source or a drain of an MOS transistor or an emitter or a collector of a bipolar transistor or a cathode or anode of a diode, and a control electrode means an element of the device that controls current through the device such as a gate of an MOS transistor or a base of a bipolar transistor. Although the devices are explained herein as certain N-channel or P-Channel devices, a person of ordinary skill in the art will appreciate that complementary devices are also possible in accordance with the present invention: It will be appreciated by those skilled in the art that the words during, while, and when as used herein are not exact terms that mean an action takes place instantly upon an initiating action but that there may be some small but reasonable delay, such as a propagation delay, between the reaction that is initiated by the initial action.

### DETAILED DESCRIPTION OF THE DRAWINGS

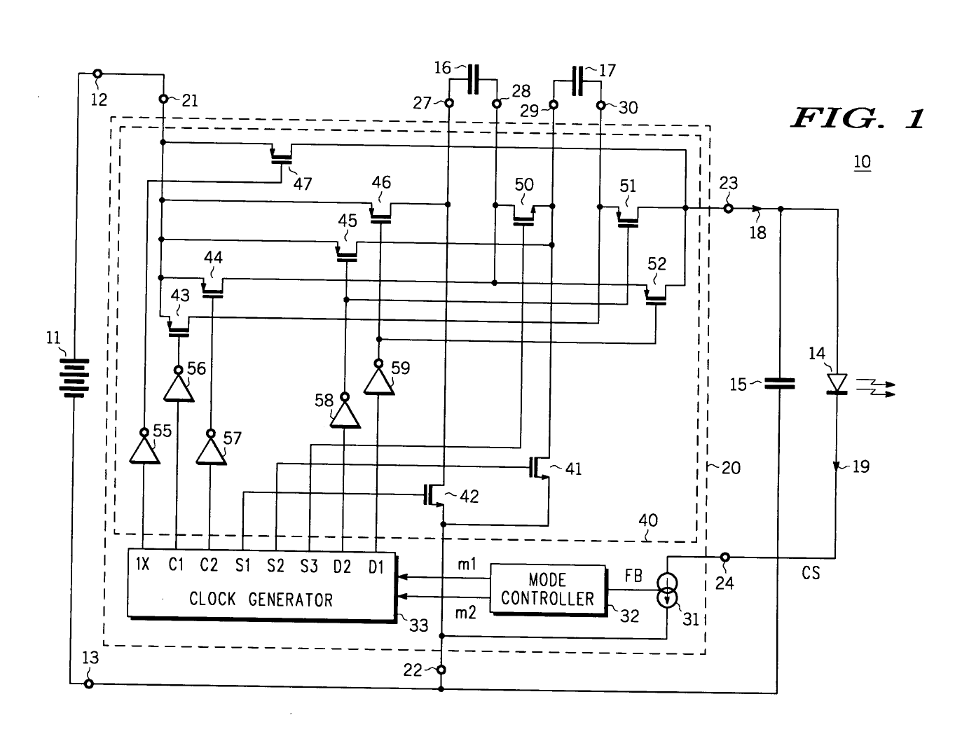

FIG. 1 schematically illustrates an embodiment of a portion of a charge pump power supply system 10 that includes an exemplary embodiment of a charge pump controller 20. System 10 receives power from a DC voltage source, such as a battery 11, between a voltage input terminal 12 and a voltage return terminal 13, and forms an output voltage that is supplied to load, such as a light emitting diode (LED) 14, along with a load current 18. Load current 18 is also used to charge an output capacitor 15 that is used to assist in maintaining the output voltage at a desired voltage value. A portion of load current 18 flows through LED 14 as an LED current 19.

Charge pump controller 20 receives an input voltage between a voltage input 21 and a voltage return 22 and supplies the output voltage on an output 23 of controller 20. Input 21 generally is connected to terminal 12 and return 22 generally is connected terminal 13. As will be seen further hereinafter, controller 20 is configured to charge a plurality of charge pump capacitors or pump capacitors, such as pump capacitors 16 and 17, during a charging time interval and to sequentially couple capacitor 16 and then capacitor 17 to supply current 18 during a plurality of discharge time intervals that occur sequentially or in series. Controller 20 includes a clock generator circuit or clock generator 33, a switch control circuit 40, a mode control circuit or mode controller 32, and a current source 31. Generator 33 or circuit 40 together with generator 33 may be viewed as a control circuit. Current source 31 is configured to receive current 19 from LED 14 through a current source (CS) input 24 and form a feedback (FB) signal that is representative of the state of current 19. If the value of current 19 is no less than the desired threshold level, the FB signal low to indicate that the value of current 19 is no less than a desired minimum value. If the value of current 19 falls below the desired threshold level, the FB signal goes high to indicate that current 19 is lower than the desired value of current 19. Alternately to using current source 31 to form the FB signal, a current sense resistor may be place in series with input 24 to receive current 19, and the resulting voltage may be compared to a reference signal. For the exemplary embodiment illustrated in FIG. 1, mode controller 32 receives the FB signal and provides two mode control signals (M1 and M2) that are used to determine the operating mode of controller 20. Controller 20 controls charge pump capacitors 16 and 17, responsively to mode control signals M1 and M2, which allows controller 20 to operate in one of three different modes. The three operating modes are generally referred to as the 1× mode, the 1.5× mode, and the 2× mode. For the 1× mode, controller 20 couples the input voltage from input 21 directly to output 23. In the 1.5× mode, controller 20 forms an output voltage that is approximately 1.5 times the value of the voltage received on input 21. In the 2× mode, controller 20 forms the output voltage to be approximately two (2) times the value of the input voltage received on input 21.

In order to facilitate charging and discharging capacitors 16 and 17, switch control circuit 40 includes a plurality of inverters and a plurality of switches, implemented as transistors, that are used for configuring capacitors 16 and 17 to be charged and then for configuring capacitors 16 and 17 to assist in supplying current 18. Circuit 40 includes inverters 55, 56, 57, 58, and 59 and also includes transistors 41, 42, 43, 44, 45, 46, 47, 50, 51, and 52. Clock generator 33 generates a plurality of timing signals that are used to control the state of the switches of circuit 40.

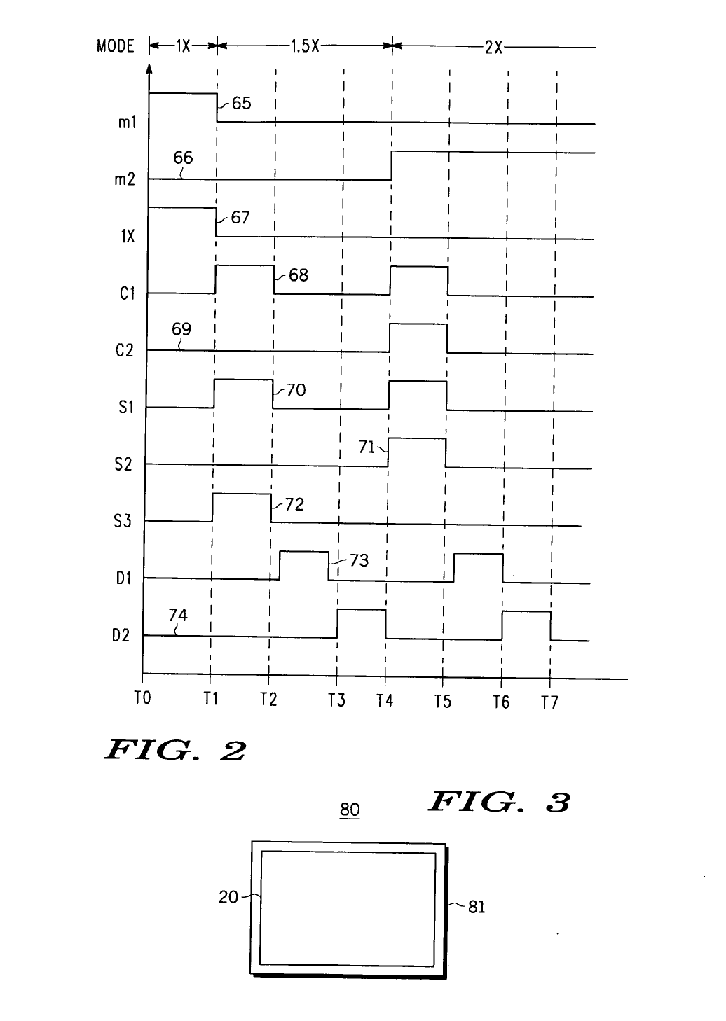

FIG. 2 is a graph having plots that illustrate some of the signals formed during the operation of controller 20. The abscissa indicates time and the ordinate indicates increasing value of the illustrated signal. Plots 65 and 66 respectively illustrate the M1 and M2 control signals that are generated by controller 32. This description has references to both FIG. 1 and FIG. 2. A plot 67 illustrates the state of a 1× control signal that is formed by generator 33. Plots 68 and 69 illustrate the state of a first charging clock (C1) signal and a second charging clock (C2) control signal that are formed by generator 33. Plots 70, 71, and 72 illustrate the state of low side control signals S1, S2, and S3 that are generated by generator 33. Plots 73 and 74 illustrate the state of sequential discharge control signals D1 and D2 that are formed by clock generator 33. Both discharge control signals D1 and D2 generally are negated for entire the time of the charging time interval that capacitors 16 and 17 are charged. Subsequently to the charging time interval, controller 20 forms a plurality of discharge time intervals so that discharge control signals D1 and D2 are generated in a serial manner. Signal D1 is asserted and signal D2 is negated during a first discharge time interval and signal D2 is asserted and signal D1 is negated during a second discharge time interval that is sequential to the first discharge time interval.

For the purpose of describing the operation of controller 20, assume that at a time T0 battery 11 is fully charged and the value of current 19 through LED 14 is no less than the desired value and is sufficient for capacitor 15 to maintain a voltage that is substantially equal to the voltage of battery 11. Current 19 flowing through current sense (CS) input 24 causes the feedback (FB) signal to be low. Mode controller 32 receives the low feedback (FB) signal and responsively forces the M1 control signal high and the M2 control signal low which signals clock generator 33 to operate in the 1× mode. In the 1× mode, generator 33 forces the 1× control signal high thereby forcing the output of inverter 55 low and enabling transistor 47. Enabling transistor 47 couples the voltage from input 21 to output 23 so that the output voltage is substantially equal to the value of the voltage from battery 11, minus minor losses such as through transistor 47. In the 1× operating mode, clock generator 33 forces the C1, C2, S1, S2, S3, D1, and D2 control signals low thereby disabling respective transistors 43, 44, 42, 41, 50, 45, and 46. Consequently, in the 1× mode, generator 33 does not switch charge pump capacitors 16 and 17 to be charged from battery 11 or to supply current 18.

Assume that at a time T1 the value of current 19 decreases to a value that is less than the threshold value which forces the FB signal high. Controller 32 receives the high FB signal which indicates controller 20 needs to increase the value of the output voltage on output 23 in order to supply the desired value for current 19, thus, controller 32 forces the M1 and M2 signals low to cause controller 20 to operate in the 1.5× mode. In the 1.5× mode, clock generator 33 is configured to form a charging time interval during which capacitors 16 and 17 are coupled in series and this series combination is coupled in parallel with battery 11 so the capacitors 16 and 17 are each charged to a voltage value that is approximately one-half of the voltage from battery 11. During this charging time interval between times T1 and T2, controller 33 forces the 1× control signal low, the C1 control signal high, the C2 control signal low, the S1 control signal high, the S2 control signal low, and the S3 control signal high. Discharge control signals D1 and D2 typically are always low during the charging time interval. The high C1 control signal and low C2 control signal enables transistor 43 and disables transistor 44. The low S2 control signal disables transistor 41 while the high S1 and S3 control signals enable transistors 42 and 50. Since discharge control signals D1 and D2 are both low, transistors 45, 46, 51, and 52 are disabled. With transistors 42, 43, and 50 enabled, the input voltage from input 21 is coupled through transistor 43 to capacitor terminal 30, capacitor terminal 29 is coupled to capacitor terminal 28 through transistor 50, and capacitor terminal 27 is coupled to return 22 through transistor 42. Thus, capacitors 16 and 17 are each charge to a voltage that is approximately one-half the voltage from battery 11. The time used for the charging time interval between T1 and T2 is chosen to be long enough to ensure that capacitors 16 and 17 receive a charge that is sufficient to supply current 19 and maintain capacitor 15 charged. After the charging time interval is complete at time T2, generator 33 sequentially forms a number of discharging time intervals such that the number of discharge time intervals is equal to the number of pump capacitors that are charged by controller 20. For the example embodiment illustrated in FIG. 1, generator 32 forms two discharge time intervals, one discharge time interval for each of capacitors 16 and 17. During the first discharge time interval, signal D1 is asserted and signal D2 is negated, and during the second discharge time interval signal D2 is asserted and signal D1 is negated. Thus, generator 33 sequentially forms two discharge time intervals that are defined by one of discharge control signals D1 or D2 being asserted. During the first discharge time interval after time T2 to time T3, all the control signals are low except for signal D1. Those skilled in the art will appreciate that there generally is a small amount of time between the end of time T2 and the beginning of the first discharge time interval in order to allow the transistors to be completely disabled before enabling the transistors controlled by signal D1 (often referred to as a dead time). The high D1 control signal forces the output of inverter 59 low thereby enabling transistors 46 and 52. Enabling transistor 46 couples input 21 to capacitor terminal 27 and enabling transistor 52 couples capacitor terminal 28 to output 23, thus, the voltage from battery 11 is added to the voltage of capacitor 16 thereby supplying an output voltage on output 23 that is substantially 1.5 times the value of the voltage on battery 11. When the first discharge time interval expires approximately at time T3, generator 33 sequentially forms a subsequent discharge time interval by asserting control signal D2 and negating control signal D1. Those skilled in the art realize that there generally is a dead time after negating signal D1 before signal D2 is asserted. The high D2 signal forces the output of inverter 58 low thereby enabling transistors 45 and 51. Transistor 45 couples the voltage from input 21 to capacitor terminal 29 and enabling transistor 51 couples capacitor terminal 30 to output 23 thereby forming the output voltage to be substantially 1.5 times the value of the voltage on battery 11. After the second discharge time interval expires at approximately time T4, controller 20 would typically begin another charging time interval such as the one that started at time T1. Generally, controller 20 would continue operating in the 1.5× mode as long as the value of current 19 remains above the threshold value.

Assume that the FB signal is again low and that just after time T4, current 19 decreases to a value that is less than the threshold value thereby again forcing the FB signal high. Mode controller 32 receives the high FB signal which indicates that controller 20 needs to increase the value of the output voltage on output 23 in order to supply the desired value for current 19, thus, controller 32 forces the M1 signal low and the M2 signal high to cause controller 20 to operate in the 2× mode. In the 2× mode, clock generator 33 is configured to form a charging time interval during which capacitors 16 and 17 are coupled in parallel and this parallel combination is coupled in parallel with battery 11 so the capacitors 16 and 17 are each charged to a voltage value that is approximately equal to the voltage from battery 11. During this charging time interval after time T4 and up to time T5, generator 33 forces the 1× control signal low, the C1 and C2 control signals high, the S1 and S2 control signals high, and the S3 control signal low. Discharge control signals D1 and D2 typically are always low during the charging time interval. The high C1 and C2 signals enable transistors 43 and 44. The high S1 and S2 signals enable transistors 41 and 42 while the low S3 signal disables transistor 50. Since discharge control signals D1 and D2 are both low, transistors 45, 46, 51, and 52 are disabled. With transistors 41, 42, 43, and 44 enabled, the input voltage from input 21 is coupled through transistor 43 to capacitor terminal 30, and capacitor terminal 29 is coupled to return 22 through transistor 41. Transistor 44 couples the input voltage from input 21 to capacitor terminal 28 and capacitor terminal 27 is coupled to return 22 through transistor 42. Thus, capacitors 16 and 17 are each charged to a voltage that is approximately equal to the voltage from battery 11. The time used for the charging time interval is chosen to be long enough to ensure that capacitors 16 and 17 receive a charge that is sufficient to supply current 19 and maintain capacitor 15 charged. After the charging time interval is complete at time T5, generator 33 sequentially forms a number of discharging time intervals such that the number of discharge time intervals is equal to the number pump capacitors that are charged by controller 20. For the example embodiment illustrated in FIG. 1, generator 33 forms two discharge time intervals, one discharge time interval for each of capacitors 16 and 17. During the first discharge time interval, discharge control signal D1 is asserted and signal D2 is negated, and during the second discharge time interval signal D2 is asserted and signal D1 is negated. Thus, generator 33 again sequentially forms two discharge time intervals that are defined by one of discharge control signals D1 or D2 being asserted. During the first discharge time interval after time T5 to time T6, all the control signals are low except for signal D1. Those skilled in the art will appreciate that there generally is a dead time between the end of time T5 and the beginning of the first discharge time interval. The high D1 signal forces the output of inverter 59 low thereby enabling transistors 46 and 52. Enabling transistor 46 couples input 21 to capacitor terminal 27 and enabling transistor 52 couples capacitor terminal 28 to output 23, thus, the voltage from battery 11 is added to the voltage of capacitor 16 thereby supplying an output voltage on output 23 that is substantially two (2) times the value of the voltage on battery 11. When the first discharge time interval expires approximately at time T6, generator 33 sequentially forms a subsequent second discharge time interval by negating control signal D1 and, after a dead time, asserting signal D2. The high D2 signal forces the output of inverter 58 low thereby enabling transistors 45 and 51. Transistor 45 couples the voltage from input 21 to capacitor terminal 29 and enabling transistor 51 couples capacitor terminal 30 to output 23 thereby forming the output voltage to be substantially two (2) times the value of the voltage on battery 11. After the second discharge time interval expires at approximately time T7, controller 20 would typically begin another charging time interval such as the one that started at approximately time T4. Generally, controller 20 would continue operating in the 2× mode as long as the value of current 19 remains above the threshold value. Typically, other circuitry, not shown, would assist in forming signals that assist in causing controller 20 to switch back to the 1× or 1.5× mode.

In order to facilitate this functionality for controller 20, input 24 is connected to one terminal of current source 31. The FB output of source 31 is connected to an input of controller 32. The M1 control signal from controller 32 is connected to first input of generator 33 and the M2 signal from controller 32 is connected to a second input of generator 33. The 1× output of generator 33 is connected to an input of inverter 55 which has an output connected to a gate of transistor 47. The C1 output of generator 33 is connected to an input of inverter 56 which has an output connected to a gate of transistor 43. The C2 output of generator 33 is connected to an input of inverter 57 which has an output connected to a gate of transistor 44. The S1 output of generator 33 is connected to a gate of transistor 42. The S2 output of generator 33 is connected to a gate of transistor 41. The S3 output of generator 33 is connected to a gate of transistor 50. The D1 output of generator 33 is connected to an input of inverter 59 which has an output commonly connected to a gate of transistor 46 and a gate of transistor 52. The D2 output of generator 33 is connected to an input of inverter 58 which has an output commonly connected to a gate of transistor 45 and a gate of transistor 51. Input 21 is commonly connected to a source of transistor 47, a source of transistor 46, a source of transistor 45, a source of transistor 44, and a source of transistor 43. A drain of transistor 47 is commonly connected to output 23, a drain of transistor 51, and a drain of transistor 52. A drain of transistor 46 is commonly connected to terminal 27 and a drain of transistor 42. A drain of transistor 45 is commonly connected to terminal 29, a source of transistor 50, and a drain of transistor 41. A drain of transistor 44 is commonly connected to terminal 28, a drain of transistor 50, and a source of transistor 52. A drain of transistor 43 is commonly connected to terminal 30 and a source of transistor 51. A source of transistor 41 is commonly connected to a source of transistor 42, a second terminal of current source 31, and to return 22.

FIG. 3 schematically illustrates an enlarged plan view of a portion of an embodiment of a semiconductor device or integrated circuit 80 that is formed on a semiconductor die 81. Controller 20 is formed on die 81. Die 81 may also include other circuits that are not shown in FIG. 3 for simplicity of the drawing. Controller 20 and device or integrated circuit 80 are formed on die 81 by semiconductor manufacturing techniques that are well known to those skilled in the art.

In view of all of the above, it is evident that a novel device and method is disclosed. Included, among other features, is forming a charge pump controller to charge a plurality of pump capacitors during a charging time interval and to sequentially form a plurality of discharge time intervals with a different pump capacitor coupled to supply a current to a load for each discharge time interval.

While the subject matter of the invention is described with specific preferred embodiments, it is evident that many alternatives and variations will be apparent to those skilled in the semiconductor arts. More specifically the subject matter of the invention has been described for a particular embodiment that uses two pump capacitors. However, the technique is applicable to using more that two pump capacitors. The number of sequential discharge intervals is usually chosen to be the same as the number of capacitors that are charged during the charging time interval.

1. A charge pump controller comprising:
a plurality of terminals configured for coupling to a plurality of pump capacitors;
an output configured to supply a load current to a load; and
a control circuit configured to form a charging time interval for charging a first pump capacitor of the plurality of pump capacitors and to sequentially form a plurality of discharge time intervals for sequentially coupling the plurality of pump capacitors to supply current to the output.

2. The charge pump controller of claim 1 wherein the control circuit sequentially forms the plurality of discharge time intervals after forming the charging time interval.

3. The charge pump controller of claim 1 wherein the control circuit sequentially forms the plurality of discharge time intervals prior to forming another charging time interval.

4. The charge pump controller of claim 1 wherein the charge pump controller is configured to couple at least two pump capacitors of the plurality of pump capacitors in parallel to charge the at least two pump capacitors to a first voltage during the charging time interval and to sequentially select a pump capacitor from the at least two pump capacitors to supply the current to the output responsively to each sequential discharge time interval of the plurality of discharge time intervals.

5. The charge pump controller of claim 1 wherein the charge pump controller is configured to couple at least two pump capacitors of the plurality of pump capacitors in parallel to charge the at least two pump capacitors to a first voltage during the charging time interval and subsequently to select a first pump capacitor of the at least two pump capacitors to supply the current to the output responsively to a first discharge time interval of the plurality of discharge time intervals and to sequentially select a second pump capacitor of the at least two pump capacitors to supply the current to the output responsively to a second discharge time interval of the plurality of discharge time intervals.

6. The charge pump controller of claim 1 wherein the charge pump controller is configured to couple the plurality of pump capacitors in series to charge each charge pump capacitor to a first voltage during the charging time interval and to sequentially select different pump capacitors from the plurality of capacitors to the output responsively to each sequential discharge time interval of the plurality of discharge time intervals.

7. The charge pump controller of claim 1 wherein the charge pump controller is configured to couple at least two pump capacitors of the plurality of pump capacitors in series to charge the at least two pump capacitors to a first voltage during the charging time interval and subsequently to select a first pump capacitor of the at least two pump capacitors to supply the current to the output responsively to a first discharge time interval of the plurality of discharge time intervals and to sequentially select a second pump capacitor of the at least two pump capacitors to supply the current to the output responsively to each a second discharge time interval of the plurality of discharge time intervals.

8. The charge pump controller of claim 1 wherein a number of discharge time intervals of the plurality of discharge time intervals is no greater than a number of pump capacitors of the plurality of pump capacitors.

9. The charge pump controller of claim 1 wherein the control circuit asserts a plurality of control signal during the charging time interval and sequentially asserts a single discharge control signal for each of the plurality of discharge time intervals.

10. A method of forming a charge pump controller comprising:
configuring the charge pump controller to charge a plurality of pump capacitors to a first voltage during a charging time interval; and
configuring the charge pump controller to sequentially couple each pump capacitor of the plurality of pump capacitors to supply current to a load.

11. The method of claim 10 wherein configuring the charge pump controller to charge the plurality of pump capacitors includes configuring the charge pump controller to couple two charge pump capacitors in parallel to charge the two pump capacitors.

12. The method of claim 11 wherein configuring the charge pump controller to sequentially couple each pump capacitor includes configuring the charge pump controller to couple a first pump capacitor of the two charge pump capacitors to supply current to the load while not coupling a second pump capacitor of the two charge pump capacitors to supply current to the load, then to sequentially couple the second pump capacitor of the two charge pump capacitors to supply current to the load while not coupling the first pump capacitor of the two charge pump capacitors to supply current to the load.

13. The method of claim 10 wherein configuring the charge pump controller to charge the plurality of pump capacitors includes configuring the charge pump controller to couple two charge pump capacitors in series to charge the two pump capacitors.

14. The method of claim 13 wherein configuring the charge pump controller to sequentially couple each pump capacitor includes configuring the charge pump controller to couple a first charge pump capacitor of the two charge pump capacitors to supply current to the load while not coupling a second charge pump capacitor of the two charge pump capacitors to supply current to the load, then to sequentially couple the second charge pump capacitor of the two charge pump capacitors to supply current to the load while not coupling the first charge pump capacitor of the two charge pump capacitors to supply current to the load.

15. The method of claim 10 wherein configuring the charge pump controller to sequentially couple each pump capacitor of the plurality of pump capacitors to supply current to the load includes configuring the charge pump controller to sequentially couple each pump capacitor of the plurality of pump capacitors to supply current prior to after the charging time interval and prior to forming another charging time interval.

16. The method of claim 10 wherein configuring the charge pump controller to sequentially couple each pump capacitor of the plurality of pump capacitors to supply current to the load includes configuring the charge pump controller to form a plurality of discharge time intervals and to couple at different pump capacitor of the plurality of pump capacitors to an output of the charge pump controller responsively to each discharge time interval of the plurality of discharge time intervals.
